(19) United States
(12) Patent Application Publication
(10) Pub. No.: US 2016/0370706 A1
(43) Pub. Date: Dec. 22, 2016

(54) EXTREME ULTRAVIOLET LIGHT GENERATION APPARATUS

(71) Applicant: GIGAPHOTON INC., Tochigi (JP)

(72) Inventors: Naoyoshi IMACHI, Oyama-shi (JP); Osamu WAKABAYASHI, Oyama-shi (JP)

(73) Assignee: GIGAPHOTON INC., Tochigi (JP)

(21) Appl. No.: 15/256,762

(22) Filed: Sep. 6, 2016

Related U.S. Application Data
(63) Continuation of application No. PCT/JP2014/061815, filed on Apr. 28, 2014.

(51) Int. Cl. G03F 7/20

(52) U.S. Cl. CPC G03F 7/70033

(57) ABSTRACT

An extreme ultraviolet light generation apparatus may include: a target supply device configured to supply targets from a nozzle; a first illumination device configured to output light having a first characteristic to illuminate targets outputted from the nozzle; a second illumination device configured to output light having a second characteristic different from the first characteristic to illuminate the targets outputted from the nozzle; a first imaging device configured to photograph light reflected off the targets illuminated with the light having the first characteristic; and a second imaging device configured to photograph light reflected off the targets illuminated with the light having the second characteristic.

### CROSS-REFERENCE TO RELATED APPLICATIONS

The present application is a continuation application of International Application No. PCT/JP2014/61815 filed on Apr. 28, 2014, the content of which is hereby incorporated by reference into this application.

### BACKGROUND

### 1. Technical Field

The present disclosure relates to an extreme ultraviolet light generation apparatus.

### 2. Related Art

In recent years, semiconductor production processes have become capable of producing semiconductor devices with increasingly fine feature sizes, as photolithography has been making rapid progress toward finer fabrication. In the next generation of semiconductor production processes, microfabrication with feature sizes at 70 nm to 45 nm, and further, microfabrication with feature sizes of 32 nm or less will be required. In order to meet the demand for microfabrication with feature sizes of 32 nm or less, for example, an exposure apparatus is needed in which a system for generating extreme ultraviolet (EUV) light at a wavelength of approximately 13 nm is combined with a reduced projection reflective optics.

Three kinds of systems for generating EUV light are known in general, which include a Laser Produced Plasma (LPP) type system in which plasma is generated by irradiating a target material with a laser beam, a Discharge Produced Plasma (DPP) type system in which plasma is generated by electric discharge, and a Synchrotron Radiation (SR) type system in which orbital radiation is used to generate plasma.

### CITATION LIST

### Patent Literature

PTL1: U.S. Pat. No. 7,164,144

PTL2: U.S. Pat. No. 7,087,914

PTL3: U.S. Patent Application Publication No. 2010/294958 A1

### SUMMARY

An example of an extreme ultraviolet light generation apparatus in the present disclosure may include a target supply device for supplying targets from a nozzle, a first illumination device for outputting light having a first characteristic to illuminate the targets outputted from the nozzle, a second illumination device for outputting light having a second characteristic different from the first characteristic to illuminate the targets outputted from the nozzle, a first imaging device for photographing the targets illuminated with the light having the first characteristic, and a second imaging device for photographing the targets illuminated with the light having the second characteristic.

### BRIEF DESCRIPTION OF THE DRAWINGS

Hereinafter, selected embodiments of the present disclosure will be described with reference to the accompanying drawings.

FIG. 1 schematically illustrates an exemplary configuration of an LPP type EUV light generation system.

FIG. 2 schematically illustrates a comparative example of an extreme ultraviolet light generation apparatus including a target trajectory measurement device.

FIG. 3 illustrates an embodiment of a control system for controlling the target trajectory to pass through the targeted central point of the plasma generation region through measurement of the target trajectory.

FIG. 4 illustrates an image of targets irradiated from two directions.

FIG. 5 illustrates an embodiment of a target trajectory measurement device including illumination devices that output illumination light having wavelengths different from each other.

FIG. 6 illustrates an embodiment of a target trajectory measurement device including illumination devices that output illumination light asynchronously with each other.

FIG. 7 illustrates operation timing of the illumination devices and the imaging devices.

FIG. 8 illustrates an embodiment of a target trajectory measurement device including illumination devices that output illumination light polarized differently from each other.

### DETAILED DESCRIPTION

### <Contents>

1. Overview
2. Terms
3. Overview of EUV Light Generation System
4. Comparative Example of Extreme Ultraviolet Light Generation Apparatus Including Target Trajectory Measurement Device
5. Embodiment 1: Target Trajectory Measurement Device Including Illumination Devices That Output Illumination Light having Wavelengths Different from Each Other
6. Embodiment 2: Target Trajectory Measurement Device Including Illumination Devices That Output Illumination Light Asynchronously with Each Other
7. Embodiment 3: Target Trajectory Measurement Device Including Illumination Devices That Output Illumination Light Polarized Differently from Each Other

Hereinafter, selected embodiments of the present disclosure will be described in detail with reference to the accompanying drawings. The embodiments to be described below are merely illustrative in nature and do not limit the scope of the present disclosure. Further, the configuration(s) and operation(s) described in each embodiment are not all essential in implementing the present disclosure. Note that like elements are referenced by like reference numerals and characters, and duplicate descriptions thereof will be omitted herein.

### 1. Overview

In measuring a trajectory of a target, conventional trajectory control systems illuminate a target from two directions and measure the trajectory of the target from two directions. For this reason, two images of the trajectory of the target illuminated by two light beams may be obtained and used in measurement to cause inaccuracy in the measurement of the target trajectory.

An example of an extreme ultraviolet light generation apparatus in the present disclosure may include a target supply device for supplying targets from a nozzle, a first illumination device for outputting light having a first characteristic to illuminate the targets outputted from the nozzle, a second illumination device for outputting light having a second characteristic different from the first characteristic to illuminate the targets outputted from the nozzle, a first imaging device for photographing the targets illuminated with the light having the first characteristic, and a second imaging device for photographing the targets illuminated with the light having the second characteristic.

Since the two illumination devices irradiate the targets with light having characteristics different from each other and two imaging devices photograph the light having the different characteristics to measure the trajectories of the targets, the accuracy in measuring the target trajectory may improve.

### 2. Terms

A term used in the present disclosure will be described hereinafter. A “trajectory” of a target is an actual path of a target outputted from the target supply device.

### 3. Overview of EUV Light Generation System

### 3.1 Configuration

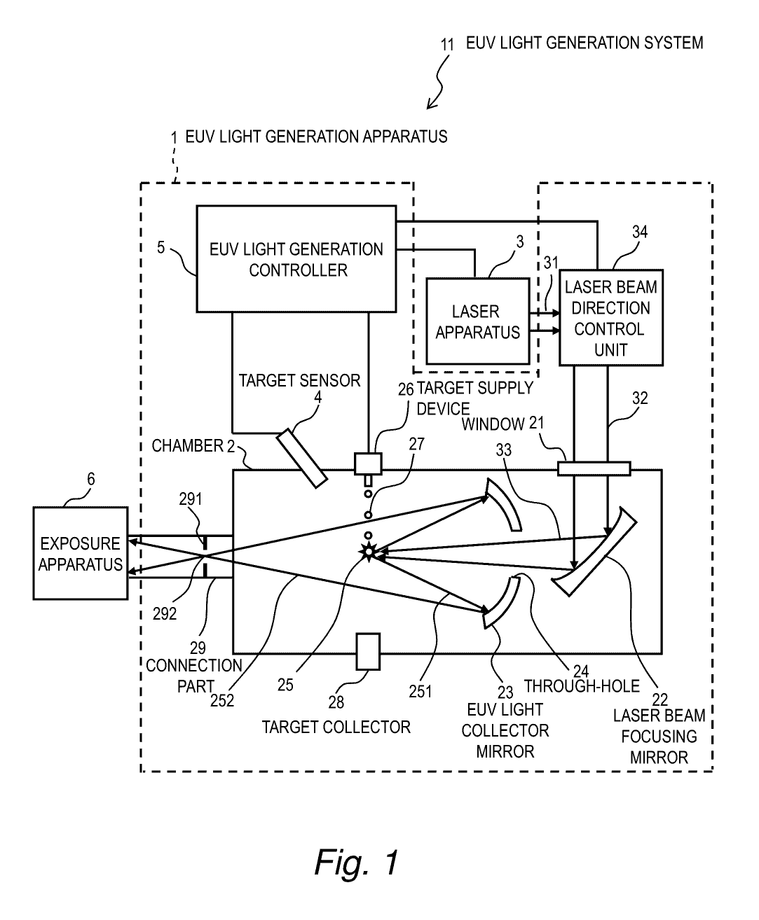

FIG. 1 schematically illustrates an exemplary configuration of an LPP type EUV light generation system. An EUV light generation apparatus 1 may be used with at least one laser apparatus 3. Hereinafter, a system that includes the EUV light generation apparatus 1 and the laser apparatus 3 may be referred to as an EUV light generation system 11. As shown in FIG. 1 and described in detail below, the EUV light generation apparatus 1 may include a chamber 2 and a target supply device 26.

The chamber 2 may be sealed airtight. The target supply device 26 may be mounted onto the chamber 2, for example, to penetrate a wall of the chamber 2. A target material to be supplied by the target supply device 26 may be, but is not limited to, tin, terbium, gadolinium, lithium, xenon, or a mixture of any two or more of these.

The chamber 2 may have at least one through-hole or opening formed in its wall. The chamber 2 may have a window 21, at the through-hole, through which the pulse laser beam 32 outputted from the laser apparatus 3 may travel into the chamber 2. An EUV light collector mirror 23, for example, having a spheroidal reflecting surface may be provided in the chamber 2. The EUV light collector mirror 23 may have a first focus and a second focus.

The EUV light collector mirror 23 may have a multi-layered reflective film formed on the spheroidal surface thereof. The reflective film may include, for example, a molybdenum layer and a silicon layer, which are alternately laminated. The EUV light collector mirror 23 may be positioned such that the first focus lies in a plasma generation region 25 and the second focus lies in an intermediate focus (IF) region 292. The EUV light collector mirror 23 may have a through-hole 24 formed at the center thereof so that a pulse laser beam 33 may travel through the through-hole 24.

The EUV light generation system 11 may further include an EUV light generation controller 5 and a target sensor 4. The target sensor 4 may have an imaging function and detect at least one of the presence, trajectory, position, and speed of a target 27. The target 27 may also be referred to as a droplet 27.

Further, the EUV light generation apparatus 1 may include a connection part 29 for allowing the interior of the chamber 2 to be in communication with the interior of the exposure apparatus 6. A wall 291 having an aperture may be provided in the connection part 29. The wall 291 may be positioned such that the second focus of the EUV light collector mirror 23 lies in the aperture formed in the wall 291.

The EUV light generation apparatus 1 may also include a laser beam direction control unit 34, a laser beam focusing mirror 22, and a target collector 28 for collecting targets 27. The laser beam direction control unit 34 may include an optical element for defining the direction into which the laser beam travels and an actuator for adjusting the position and the orientation or posture of the optical element.

### 3.2 Operation

With continued reference to FIG. 1, a pulse laser beam 31 outputted from the laser apparatus 3 may pass through the laser beam direction control unit 34 and be outputted therefrom as the pulse laser beam 32. The pulse laser beam 32 may travel through the window 21 and enter the chamber 2. The pulse laser beam 32 may travel inside the chamber 2 along at least one beam path, be reflected by the laser beam focusing mirror 22, and strike at least one target 27 as a pulse laser beam 33.

The target supply device 26 may be configured to output the target(s) 27 toward the plasma generation region 25 in the chamber 2. The target 27 may be irradiated with at least one pulse of the pulse laser beam 33. Upon being irradiated with the pulse laser beam 33, the target 27 may be turned into plasma, and rays of light 251 including EUV light may be emitted from the plasma.

At least the EUV light 252 included in the light 251 may be reflected selectively by the EUV light collector mirror 23. EUV light 252, which is the light reflected by the EUV light collector mirror 23, may travel through the intermediate focus region 292 and be outputted to the exposure apparatus 6. Here, the target 27 may be irradiated with multiple pulses included in the pulse laser beam 33.

The EUV light generation controller 5 may be configured to integrally control the EUV light generation system 11. The EUV light generation controller 5 may be configured to process image data of the target 27 captured by the target sensor 4. Further, the EUV light generation controller 5 may be configured to control at least one of: the timing when the target 27 is outputted and the direction into which the target 27 is outputted.

Furthermore, the EUV light generation controller 5 may be configured to control at least one of: the timing when the laser apparatus 3 oscillates, the direction in which the pulse laser beam 32 travels, and the position at which the pulse laser beam 33 is focused. It will be appreciated that the various controls mentioned above are merely examples, and other controls may be added as necessary.

### 4. Comparative Example of Extreme Ultraviolet Light Generation Apparatus Including Target Trajectory Measurement Device

The present disclosure relates to an extreme ultraviolet light generation apparatus including a device for measuring and controlling the trajectories of targets. The extreme ultraviolet light generation apparatus in the present disclosure may include a target trajectory measurement device capable of measuring the target trajectory with high accuracy and controlling the target trajectory based on the detection result of the target trajectory measurement device.

### 4.1 Configuration

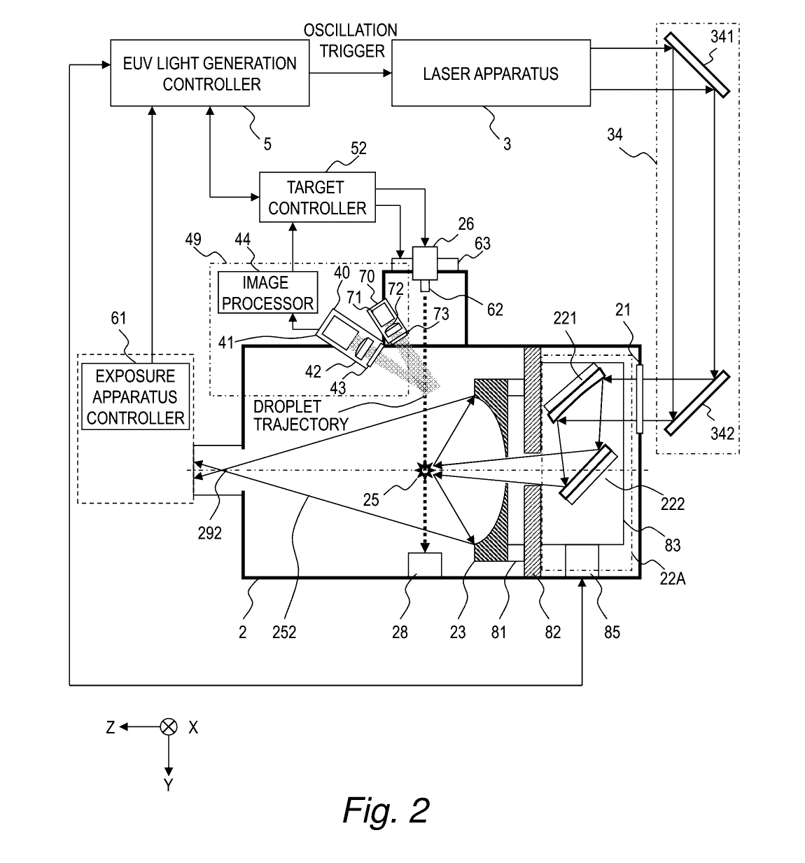

FIG. 2 schematically illustrates a comparative example of an extreme ultraviolet light generation apparatus including a target trajectory measurement device.

The EUV light generation apparatus 1 may include an EUV chamber 2, a laser apparatus 3, a beam delivery system (laser beam direction control unit) 34, an EUV light generation controller 5, and a target controller 52.

The EUV chamber 2 may include a target supply device 26, a two-axis stage 63, a target trajectory measurement device 49, a window 21, laser beam focusing optics 22A, a plate 83, a plate 82, an EUV light collector mirror holder 81, an EUV light collector mirror 23, and a target collector 28.

The target trajectory measurement device 49 may include at least two illumination devices 70 and at least two imaging devices 40. FIG. 2 shows only one illumination device 70 and only one imaging device 40. The illumination device 70 may include a light source 71, a lens 72, and a window 73. The light source 71 may be a lamp, an LED, or a laser light source, for example. The lens 72 may be a collimator lens, for example.

The imaging device 40 may include an image sensor 41, transfer optics 42, and a window 43. The image sensor 41 may be a two-dimensional CCD sensor. The transfer optics 42 and the image sensor 41 may be disposed in such an arrangement that the reflection from a target will form an image on the image sensor 41.

The target supply device 26 may be set to the chamber 2 with the two-axis stage 63 that is capable of moving in the directions of the X-axis and the Y-axis.

### 4.2 Operation

The target controller 52 may receive positional information on the central point Pt of the plasma generation region 25 to be targeted from the exposure apparatus controller 61 via the EUV light generation controller 5. The laser beam focusing optics 22A may control the focal point of the laser beam to agree with the point Pt by moving the plate 83 with a three-axis stage 85.

The EUV light generation controller 5 may send an output signal for outputting a target to the target controller 52. Upon receipt of the target output signal from the EUV light generation controller 5, the target controller 52 may control the target supply device 26 to output a target (droplet) from the nozzle 62. When the outputted target is illuminated with the light from the illumination device 70, the image of the target may be formed on the image sensor 41 through the transfer optics 42. In this operation, the exposure time of the image sensor 41 may be prolonged until a specific time. If the exposure time of the image sensor 41 is prolonged, the image of a trajectory along which the droplet has moved may be captured.

The imaging device 40 may send a target trajectory measurement signal to the image processor 44. The image processor may process the images of a target captured by two image sensors 41. The image processor 44 may calculate the trajectory of the target from the pair of image-processed data. The target trajectory measurement device 49 may measure the target trajectory in this way.

The target controller 52 may control the position of the target supply device 26 by sending a control signal based on the target trajectory calculated by the image processor 44 to the two-axis stage 63 so that the target will reach the central point Pt of the plasma. Specifically, the target controller 52 may calculate the offsets of the target trajectory from the desired position in the two images, determine the adjustment amount for the two-axis stage 63 from the calculated offsets, and send a control signal so that the two-axis stage 63 will move by the determined adjustment amount.

When the laser apparatus 3 receives an oscillation trigger signal from the EUV light generation controller 5 synchronously with output of a droplet from the target supply device 26, the laser apparatus 3 may output a pulse laser beam. The outputted pulse laser beam may pass through the laser beam direction control unit 34 and enter the EUV chamber 2 through the window 21. The pulse laser beam may be directed by the laser beam focusing optics 22A to reach the plasma generation region 25 and hit a droplet in a focused manner. As a result, the droplet may turn into plasma to generate EUV light 252.

### 4.3 Issues

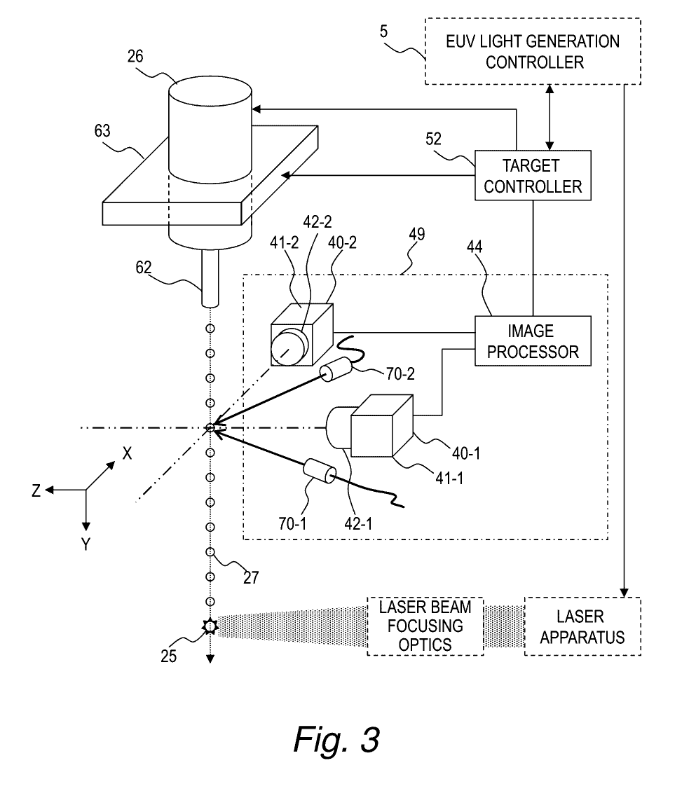

FIG. 3 illustrates an embodiment of a control system for controlling the target trajectory to pass through the targeted central point of the plasma generation region 25 through measurement of the target trajectory. FIG. 3 shows only the control system and omits the chamber.

The target trajectory measurement device 49 may include a first imaging device 40-1, a first illumination device 70-1, a second imaging device 40-2, a second illumination device 70-2, and an image processor 44.

The first illumination device 70-1 may include a light source 71-1, a lens 72-1, and a window 73-1; the second illumination device 70-2 may include a light source 71-2, a lens 72-2, and a window 73-2. The first imaging device 40-1 may include an image sensor 41-1, transfer optics 42-1, and a window 43-1. The second imaging device 40-2 may include an image sensor 41-2, transfer optics 42-2, and a window 43-2.

The first illumination device 70-1 and the second illumination device 70-2 may be disposed to illuminate a target from two directions so that the emitted light beams will intersect with each other on the target trajectory. It is preferable that the direction of emission of the first illumination device 70-1 and the direction of emission of the second illumination device 70-2 be orthogonal, but they do not need to be orthogonal. Furthermore, it is preferable that the direction of emission of the first illumination device 70-1 and the direction of emission of the second illumination device 70-2 be included in a plane perpendicular to the target trajectory; however, either one or both of the illumination devices 70 may illuminate the target from a direction not included in this plane.

The first imaging device 40-1 and the second imaging device 40-2 may be disposed in such an arrangement to capture the target in the Z-axis direction and the X-axis direction which are orthogonal to each other, but they may capture the target in directions not orthogonal to each other. The first imaging device 40-1 and the second imaging device 40-2 may be disposed at places to simultaneously capture the same target.

The two-axis stage 63 may be a stage capable of translating in the X-axis direction and the Z-axis direction. A preferable two-axis stage 63 may be a stage capable of translating in directions of two orthogonal axes, but may be a stage capable of translating in two directions which are not orthogonal, as far as it is capable of translating in two different directions.

The first imaging device 40-1 and the second imaging device 40-2 may be connected with the image processor 44. The image processor 44 and the target controller 52 may be connected so that the data outputted from the image processor 44 can be sent to the target controller 52.

Next, operation of the trajectory control system is described.

After the target supply device 26 starts outputting droplets, a plurality of droplets may travel along the trajectory. At this time, the exposure times of the two imaging devices 40-1 and 40-2 may be set to a time longer than the time for the image of a droplet to pass over the image sensor. If the exposure time is set long, the captured image of droplets may be shaped like a line. The target trajectory may be measured using this image shaped like a line.

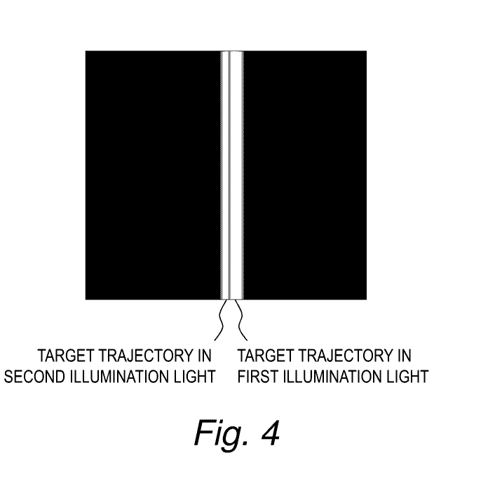

In measuring a target trajectory, existing trajectory control systems irradiate targets with light beams from two directions and measure the target trajectory from two directions as described above. In this operation, some trajectory control system may not be able to illuminate the targets with two illumination light beams in directions orthogonal to each other because of the limited space of the EUV chamber 2. Because of the same reason, some trajectory control system may not be able to measure the images of the target trajectory from the same directions as the illumination light beams. As a result, in measuring the target trajectory, images of two target trajectories illuminated from two directions may be measured. FIG. 4 illustrates an image of targets irradiated from two directions. As shown in FIG. 4, targets irradiated from two directions are captured doubly as an image of a trajectory in the first illumination light and an image of a trajectory in the second illumination light; accuracy in measurement of the target trajectory may be degraded.

### 5. Embodiment 1: Target Trajectory Measurement Device Including Illumination Devices that Output Illumination Light Having Wavelengths Different from Each Other

### 5.1 Configuration

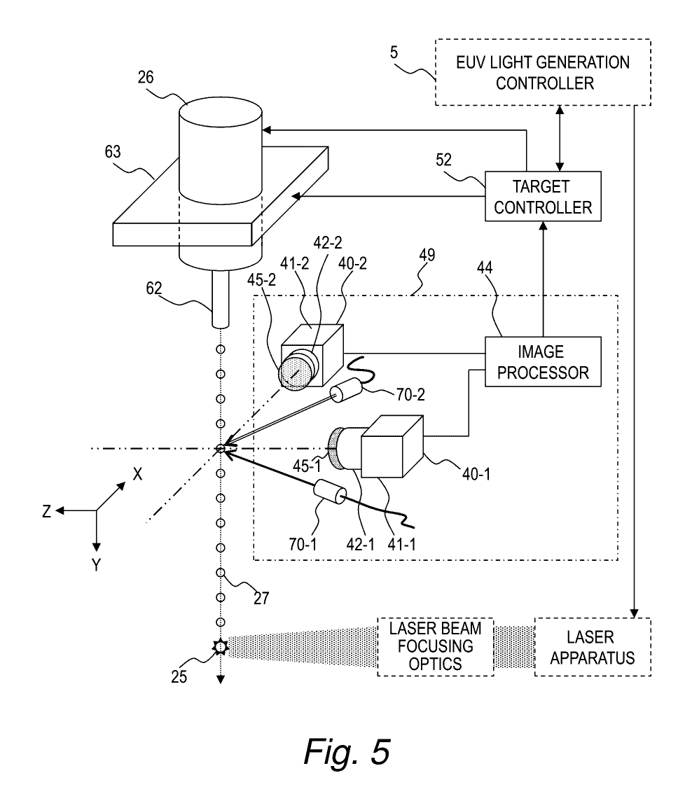

FIG. 5 illustrates an embodiment of a target trajectory measurement device 49 including illumination devices that output illumination light having wavelengths different from each other.

Hereinafter, differences from the embodiment illustrated in FIG. 3 are mainly described; the components and functions same as those in the embodiment illustrated in FIG. 3 are denoted by the same reference signs and explanation thereof is omitted.

The first illumination device 70-1 may include a light source 71-1, a lens 72-1, and a window 73-1; the second illumination device 70-2 may include a light source 71-2, a lens 72-2, and a window 73-2. The first imaging device 40-1 may include an image sensor 41-1, transfer optics 42-1, a window 43-1, and a filter 45-1; the second imaging device 40-2 may include an image sensor 41-2, transfer optics 42-2, a window 43-2, and a filter 45-2.

The light source 71-1 of the first illumination device 70-1 may be a light source for outputting light having a first wavelength and the light source 71-2 of the second illumination device 70-2 may be a light source for outputting light having a second wavelength. For example, the light source 71-1 of the first illumination device 70-1 may be a light emission diode (LED) to output light having a wavelength around 450 nm and the light source 71-2 of the second illumination device 70-2 may be a light emission diode to output light having a wavelength around 660 nm.

The filter 45-1 may be disposed on the optical path between the target trajectory and the image sensor 41-1. The filter 45-1 may be a bandpass filter to transmit a light having the first wavelength. The filter 45-2 may be disposed on the optical path between the target trajectory and the image sensor 41-2. The filter 45-2 may be a bandpass filter to transmit a light having the second wavelength. The filters may be a bandpass filter to extract the first wavelength of light and a bandpass filter to extract the second wavelength of light from the images taken by the image sensors 41-1 and 41-2, respectively, through computation.

### 5.2 Operation

The first wavelength of light outputted from the first illumination device 70-1 and the second wavelength of light outputted from the second illumination device 70-2 may illuminate the targets on the trajectory.

The first imaging device 40-1 may photograph the image of the target trajectory illuminated with the first wavelength of light through the filter 45-1. On the other hand, the second wavelength of light may be reflected or absorbed by the filter 45-1 at a high rate. The second imaging device 40-2 may photograph the image of the target trajectory illuminated with the second wavelength of light through the filter 45-2. On the other hand, the first wavelength of light may be reflected or absorbed by the filter 45-2 at a high rate.

### 5.3 Effects

In the first embodiment, the two illumination devices 70-1 and 70-2 irradiate the targets with light having wavelengths different from each other and the two imaging devices 40-1 and 40-2 take images through filters for the respective wavelengths; accordingly, each imaging device may take the image of the target trajectory illuminated with one type of illumination light. As a result, the accuracy in measuring the target trajectory may improve.

### 6. Embodiment 2: Target Trajectory Measurement Device Including Illumination Devices that Output Illumination Light Asynchronously with Each Other

### 6.1 Configuration

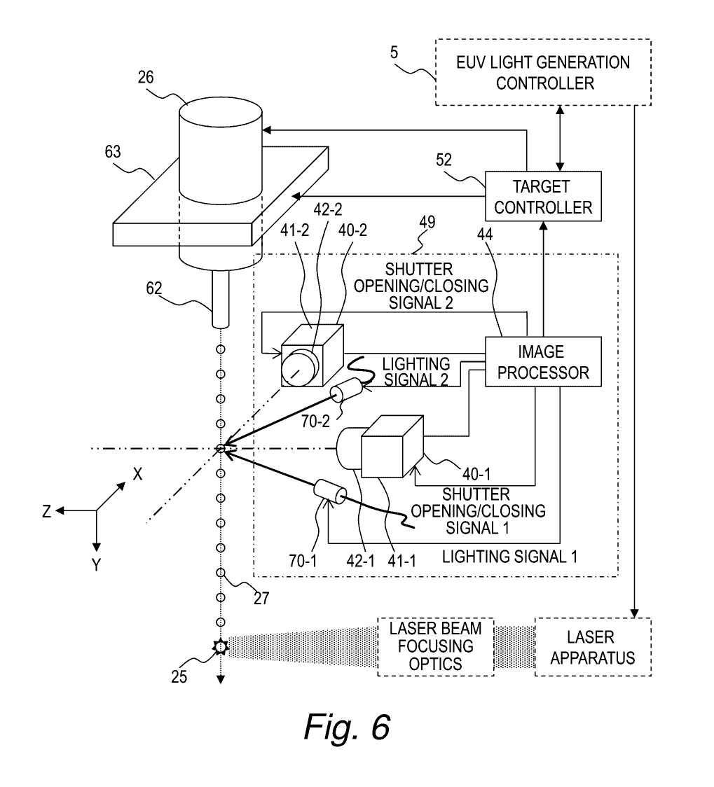

FIG. 6 illustrates an embodiment of a target trajectory measurement device 49 including illumination devices that output illumination light asynchronously with each other.

Hereinafter, differences from the embodiment illustrated in FIG. 3 are mainly described; the components and functions same as those in the embodiment illustrated in FIG. 3 are denoted by the same reference signs and explanation thereof is omitted.

The first imaging device 40-1 and the second imaging device 40-2 may include a shutter. The shutter may be an electronic shutter for a CCD, a mechanical shutter, or an image intensifier including a multichannel plate.

Control signal lines for transmitting a shutter opening/closing signal may be provided between the image processor 44 and the first imaging device 40-1 and between the image processor 44 and the second imaging device 40-2. Furthermore, control signal lines for transmitting a lighting signal may be provided between the image processor 44 and the first illumination device 70-1 and between the image processor 44 and the second illumination device 70-2.

### 6.2 Operation

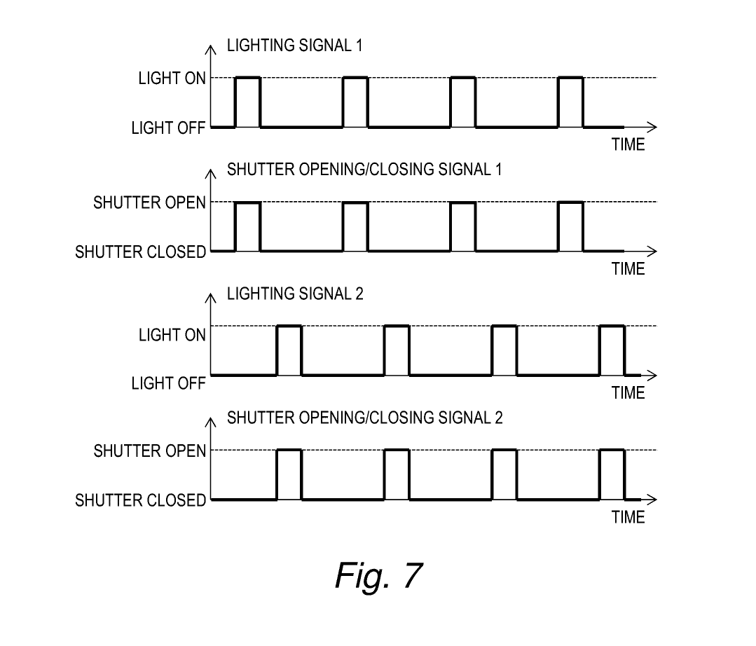

FIG. 7 illustrates operation timing of the illumination devices 70-1 and 70-2 and the imaging devices 40-1 and 40-2. The illumination devices 70-1 and 70-2 in this example illuminate the targets with such timing that lighting periods do not overlap with each other; however, the lighting periods may overlap partially with each other as far as the illumination devices 70-1 and 70-2 output light asynchronously with each other.

The image processor 44 may open the shutter of the first imaging device 40-1 simultaneously with lighting of the first illumination device 70-1. Simultaneously with the opening the shutter of the first imaging device 40-1, the targets on the trajectory may be illuminated and photographed, so that the image of the target trajectory may be captured. Simultaneously with completion of the photographing the targets, the image processor 44 may turn off the first illumination device 70-1 and close the shutter of the first imaging device 40-1.

Subsequently, the image processor 44 may open the shutter of the second imaging device 40-2 simultaneously with lighting of the second illumination device 70-2. Simultaneously with the opening the shutter of the second imaging device 40-2, the targets on the trajectory may be illuminated and photographed, so that the image of the target trajectory may be captured. Simultaneously with completion of the photographing the targets, the image processor 44 may turn off the second illumination device 70-2 and close the shutter of the second imaging device 40-2.

The image processor 44 may send control signals so that the illumination devices 70-1 and 70-2 and the imaging devices 40-1 and 40-2 will operate as described above and repeat the above-described two steps to capture the image of the target trajectory.

### 6.3 Effects

In the second embodiment, the illumination devices 70-1 and 70-2 irradiate the targets with illumination light asynchronously with each other and the imaging devices 40-1 and 40-2 capture the image of the target trajectory synchronously with lighting of the illumination devices 70-1 and 70-2; accordingly, each imaging device may capture the image of the target trajectory as an image of the illumination light from a single light source. As a result, the accuracy in measuring the target trajectory may improve.

### 7. Embodiment 3: Target Trajectory Measurement Device Including Illumination Devices that Output Illumination Light Polarized Differently from Each Other

### 7.1 Configuration

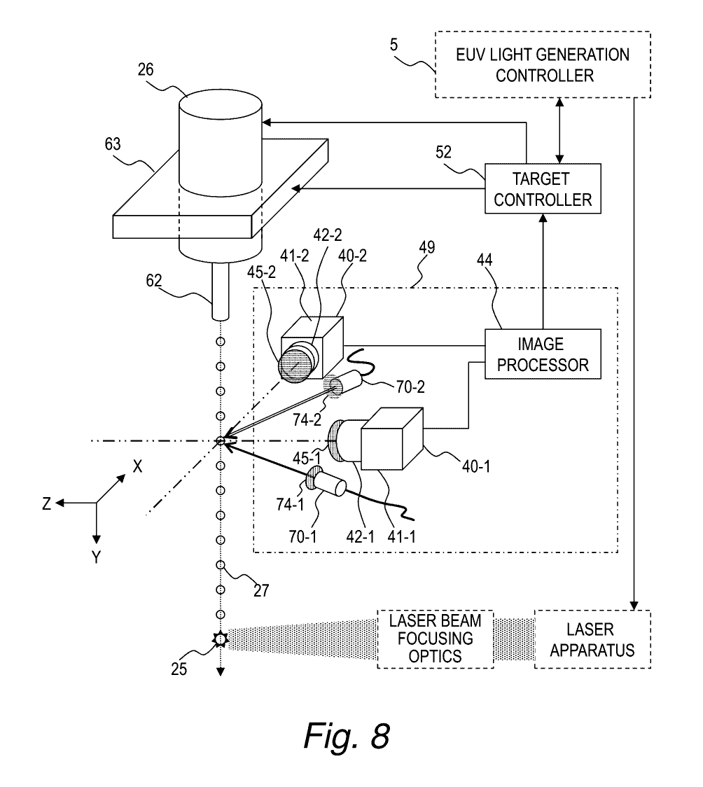

FIG. 8 illustrates an embodiment of a target trajectory measurement device 49 including illumination devices that output illumination light polarized differently from each other.

Hereinafter, differences from the embodiment illustrated in FIG. 3 are mainly described; the components and functions same as those in the embodiment illustrated in FIG. 3 are denoted by the same reference signs and explanation thereof is omitted.

The first illumination device 70-1 may include a light source 71-1, a lens 72-1, a window 73-1, and a filter 74-1; the second illumination device 70-2 may include a light source 71-2, a lens 72-2, a window 73-2, and a filter 74-2. The first imaging device 40-1 may include an image sensor 41-1, transfer optics 42-1, a window 43-1, and a filter 45-1; the second imaging device 40-2 may include an image sensor 41-2, transfer optics 42-2, a window 43-2, and a filter 45-2.

The light source of the first illumination device 70-1 may be a light source for outputting first polarized light and the light source of the second illumination device 70-2 may be a light source for outputting second polarized light. For example, a polarized light filter 74-1 for transmitting the first polarized light may be provided on the optical path between the light source 71-1 of the first illumination device 70-1 and the target trajectory and the first illumination device 70-1 may illuminate targets with the first polarized light. Furthermore, a polarized light filter 74-2 for transmitting the second polarized light different from the first polarized light may be provided on the optical path between the light source 71-2 of the second illumination device 70-2 and the target trajectory and the second illumination device 70-2 may illuminate targets with the second polarized light. It is preferable that the first polarized light and the second polarized light be different by 90° (π/2), but may be sufficient if the light can be split with the polarized light filters.

The filter 45-1 may be disposed on the optical path between the target trajectory and the image sensor 41-1. The filter 45-1 may be a polarized light filter to transmit the first polarized light. The filter 45-2 may be disposed on the optical path between the target trajectory and the image sensor 41-2. The filter 45-2 may be a polarized light filter to transmit the second polarized light.

### 7.2 Operation

The first polarized light outputted from the first illumination device 70-1 and the second polarized light outputted from the second illumination device 70-2 may illuminate targets on the trajectory.

The first imaging device 40-1 may photograph the images of the trajectories of the targets illuminated with the first polarized light through the filter 45-1. On the other hand, the second polarized light may be reflected or absorbed by the filter 45-1 at a high rate. The second imaging device 40-2 may photograph the images of the trajectories of the targets illuminated with the second polarized light through the filter 45-2. On the other hand, the first polarized light may be reflected or absorbed by the filter 45-2 at a high rate.

### 7.3 Effects

In the third embodiment, the two illumination devices 70-1 and 70-2 irradiate the targets with light polarized differently from each other and two imaging devices 40-1 and 40-2 are provided with polarized light filters for the respective polarized light to capture images; accordingly, each imaging device may capture the image of the target trajectory illuminated with one type of illumination light. As a result, the accuracy in measuring the target trajectory may improve.

As set forth above, the present invention has been described with reference to embodiments; the foregoing description is merely provided for the purpose of exemplification but not limitation. Accordingly, it is obvious for a person skilled in the art that the embodiments in this disclosure may be modified within the scope of the appended claims.

A part of the configuration of an embodiment may be replaced with a configuration of another embodiment. A configuration of an embodiment may be incorporated to a configuration of another embodiment. A part of the configuration of each embodiment may be removed, added to a different configuration, or replaced by a different configuration.

The terms used in this specification and the appended claims should be interpreted as “non-limiting”. For example, the terms “include” and “be included” should be interpreted as “including the stated elements but not limited to the stated elements”. The term “have” should be interpreted as “having the stated elements but not limited to the stated elements”. Further, the modifier “one (a/an)” should be interpreted as “at least one” or “one or more.”

What is claimed is:

1. An extreme ultraviolet light generation apparatus configured to generate EUV light by irradiating targets in a plasma generation region with a laser beam to change the targets into plasma, the extreme ultraviolet light generation apparatus comprising:
a target supply device configured to supply targets from a nozzle;
a first illumination device configured to output light having a first characteristic to illuminate targets outputted from the nozzle;
a second illumination device configured to output light having a second characteristic different from the first characteristic to illuminate the targets outputted from the nozzle;
a first imaging device configured to photograph light reflected off the targets illuminated with the light having the first characteristic; and
a second imaging device configured to photograph light reflected off the targets illuminated with the light having the second characteristic.

2. The extreme ultraviolet light generation apparatus according to claim 1, wherein the first imaging device and the second imaging device are arranged to image trajectories of the targets from different directions.

3. The extreme ultraviolet light generation apparatus according to claim 1,
wherein the first characteristic is a first wavelength, and
the second characteristic is a second wavelength.

4. The extreme ultraviolet light generation apparatus according to claim 3, further comprising:
a first filter configured to transmit light having the first wavelength, the first filter being provided on an optical path between an image pickup device of the first imaging device and the trajectories of the targets; and
a second filter configured to transmit light having the second wavelength, the second filter being provided on an optical path between an image pickup device of the second imaging device and the trajectories of the targets.

5. The extreme ultraviolet light generation apparatus according to claim 1,
wherein the first characteristic is first timing to output light,
the second characteristic is second timing to output light,
the first imaging device is configured to photograph the light reflected off the targets synchronously with the first timing, and
the second imaging device is configured to photograph the light reflected off the targets synchronously with the second timing.

6. The extreme ultraviolet light generation apparatus according to claim 5, wherein each period to output light in the second timing does not overlap with each period to output light in the first timing.

7. The extreme ultraviolet light generation apparatus according to claim 1,
wherein the first characteristic is first polarization, and
the second characteristic is second polarization.
